(19) United States
(12) Patent Application Publication
(10) Pub. No.: US 2009/0236740 A1
(43) Pub. Date: Sep. 24, 2009

(54) Window ball grid array package

(75) Inventor: Ming-Feng Wu, Kaohsiung Hsien (TW)

Correspondence Address: BIRCH STEWART KOLASCH & BIRCH, PO BOX 747, FALLS CHURCH, VA, 22040-0747, US

(73) Assignee: Integrated Circuit Solution Inc.

(21) Appl. No.: 12/155,626

(22) Filed: Jun. 6, 2008

(30) Foreign Application Priority Data
Mar. 19, 2008 (TW) 97109726

(51) Int. Cl. H01L 23/49

(52) U.S. Cl. 257/737; 257/680; 257/E23.024

(57) ABSTRACT

A WBGA (window ball grid array) semiconductor package includes a substrate having a slot as a window for a chip. The slot has four straight sections and four rounded corners respectively interconnecting adjacent two straight sides. Each rounded corner has a radius satisfying the minimum distance between the pads and the slot according to the design rule so as to increase the pad pitch in the chip. The plain area increased due to the pad pitch is suitable for ESD circuit or capacitors layout.

### FIELD OF THE INVENTION

The invention relates to a ball grid array package, and more particularly to a window ball grid array package including a substrate having a slot for passage of bonded wires. The configuration of the slot in the substrate is altered in such a manner to achieve increase of the pad pitch for two rows of contact pads formed on a central portion of the chip.

### BACKGROUND OF THE INVENTION

A chipset in the form of window ball grid array package is used in the mother board. FIG. 1 shows a conventional window ball grid array package generally includes a chip 10 formed with two rows of contact pads 15 at a central portion thereof, each row at least has more than ten contact pads, and a substrate 20 formed with a window 30 for passage of bonded wires. The substrate 20 has two rows of gold fingers 25 formed adjacent to two sides of the window 30, respectively. A plurality of bonding wires 35 are used for electrically coupling the gold fingers 25 to the contact pads 15 of the chip 10. The substrate 20 further has a plurality of solder balls 40 formed on one side surface thereof and coupled electrically to the gold fingers 25 via a plurality of conductive traces (not shown).

After the wire bonding operation, the gold fingers 25 on the substrate 20, the bonding wires 35 and the window 30 of the substrate 20 are confined within a mold (not shown). A resin is injected into the mold so as to form a first encapsulated body 50a on one side of the substrate 20, and a second encapsulated body 50 that encloses the chip 10 on the other side of the substrate 20 and that excludes the solder balls 40 therefrom.

For those engineers concerned for conducting packing of the aforesaid WBGA semiconductor, generally encounter problems concerning restriction of design rule for limiting the elongated slot 30. FIG. 2 shows a top planar view of the aforesaid WBGA semiconductor package, wherein the window 30 in fact is an elongated slot (will be named slot hereinafter) having two straight sections and two arched sections interconnecting the straight sections. The substrate 20 has two rows of gold fingers 25 formed adjacent to two sides of the slot 30. Under this situation, two rows of contact pads 15 in the chip 10 are located below the slot 30 in the substrate 20 ready for encapsulating operation.

As shown in FIG. 2, according to the design rule and prior to forming of the first encapsulated body 50a (consisting of bonding wires 35, the gold fingers 25 and the chip 10 in FIG. 1 and shown by dotted lines in FIG. 2) on the contact pads 15, a mold having first and second sides 12, 22 spaced apart by a distance d6, which is 2 mm in the maximum, is disposed on the substrate 20. The mold 8 (consisting of the first and second sides 12, 22 and an intersecting portion of the solid line and the dotted lines and the first and second sides) in fact does not enclose the slot 30 entirely, rather exposes the arched sections partially so as to permit injection of the resin during the encapsulating operation. In other words, the mold 8 is disposed on the substrate 20 and has two sides spaced by the distance d6 of 2 mm respectively enclosing the two rows of gold fingers 25 prior to injection of the resin. According to the design rule, the contact pads 15 should be spaced apart from the slot 30 by a distance 0.3 mm at least. Therefore, as best shown in FIG. 1, in case we make an arrangement that the rows of contact pads 15 are spaced from the straight sections 5 of the slot 30 by the distance d7 satisfying the design rule of 0.3 mm as mentioned above. Under this condition, the point P on the arched sections of the slot 30 is spaced apart from the contact pad 15 by the distance d1 smaller than 0.3 mm, which is against the design rule. In other words, the distance d1 is the minimum distance, not the distance d7, because the distance d7>the distance d1.

However, once we assign the distance d1 as 0.3 mm, and further deduct the limitation of the distance d3 (the minimum distance being 0.3 mm) between the straight sections 5 of the slot 30 to the first end of the gold finger 25 of the substrate 20, the longitudinal length limit d4 (the minimum 0.15 mm) of the gold finger 25, the limited distance d5 (the minimum distance 0.15) between the second end of the gold finger 25 to the first side 12 of the mold 8, we found that the maximum distance d2 between the rows of contact pads 15 is only 0.49 mm. As a matter fact, 0.49 mm is relatively small and the space between the rows of contact pads 15 is insufficient for layout of the electrostatic sensitive device and other capacitors.

In addition, the aforesaid space between the rows of contact pads 15 may cause interference to the solder needle during the wire bonding operation of the gold finger 25 to the contact pads 15, thereby decreasing the precision yield of the semiconductor package.

The restriction to the contact pad 15 and the slot 30 according to the design rule is to prevent the undesired overflow of the resin during the encapsulating process for forming the semiconductor package. The other reason is to remove the last contact pad 15a (see FIG. 2) from each of the rows relative to the respective gold finger 25, thereby disposing the distance d7 (between the pad row and the first side 5 of the slot 30) as the minimum distance. In practical view and in view of designing the chip, the more the number of the contact pad 15 in each row, the better the chip becomes in product yield. Reduction of the contact pad from the row is not the priority factor to be considered.

Elongated slots have been employed in the substrate according to the prior technology in order to avoid the aforesaid problems. When using the punch machine to form the slot in the substrate, we encounter rupture or crack at the corner of the slot due to heavy stress.

In other words, it is necessary to propose a new technique to overcome or solve the aforesaid problems.

### SUMMARY OF THE INVENTION

The object of the present invention is to propose a window ball grid array semiconductor package, in which, the design of the elongated slot in the substrate is altered in order to overcome the problems encountered during use of the prior art window ball grid array semiconductor package

In one aspect of the present invention, a window ball grid array semiconductor package is provided to include a substrate formed with an elongated slot, and a chip mounted to the substrate via the elongated slot, and has a contact pad. The elongated slot consists of four straight sections and four rounded corners, each is formed between and interconnects adjacent two of the straight sections, and has a radius of the minimum distance or a smaller distance with respect to the contact pad of the chip in order to fulfill the requirement of design rule, thereby increasing the plain area for layout of the electrostatic sensitive device and the capacitors. Moreover, the product yield of the semiconductor package is increased.

### BRIEF DESCRIPTION OF THE DRAWING

Other features and advantages of this invention will become more apparent in the following detailed description of the preferred embodiment of this invention, with reference to the accompanying drawings, in which:

FIG. 1 shows a sectional view of a prior art window ball grid array semiconductor package;

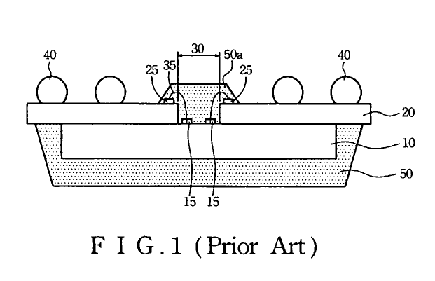

FIG. 2 is a top planar view illustrating the plan design requirement and relative position between the elongated slot and the contact pad of the chip in the prior window ball grid array semiconductor package; and

FIG. 3 is a top planar view illustrating the plan design requirement and relative position between the elongated slot and the contact pad of the chip in the window ball grid array semiconductor package of the present invention.

### DETAILED DESCRIPTIONS OF THE PREFERRED EMBODIMENT

The main problem of the prior art window ball grid array semiconductor package resides in the restriction of two arch sections of the elongated slot. When the distance d7 measured between the straight section 5 of the elongated slot 30 and the row of contact pads 15 is assigned as 0.3 mm (the minimum distance) in order to satisfy the requirement of design rule, there still remain a point “P” on the arch section of the slot 30 that is spaced apart from the contact pad 15 by a distance smaller than 0.3 mm. Such an occurrence is against the requirement of design rule. For the point “P” on the arch section to be spaced apart from the contact pad 15 by a distance 0.3 mm in order to satisfy the requirement of design rule, the distance d7 measured between the straight section 5 of the elongated slot 30 and the row of contact pads 15 should be greater than 0.3 mm. Arrangement of the distance d7 at 0.3 mm consequently minimizes the distance d2 between two rows of the contact pads 15 on the chip.

A simple technique is proposed according to the present invention in order to solve the aforesaid drawback that goes against the requirement of design rule such that under one principle of the present technique the distance between two rows of the contact pads 15 on the chip is increased.

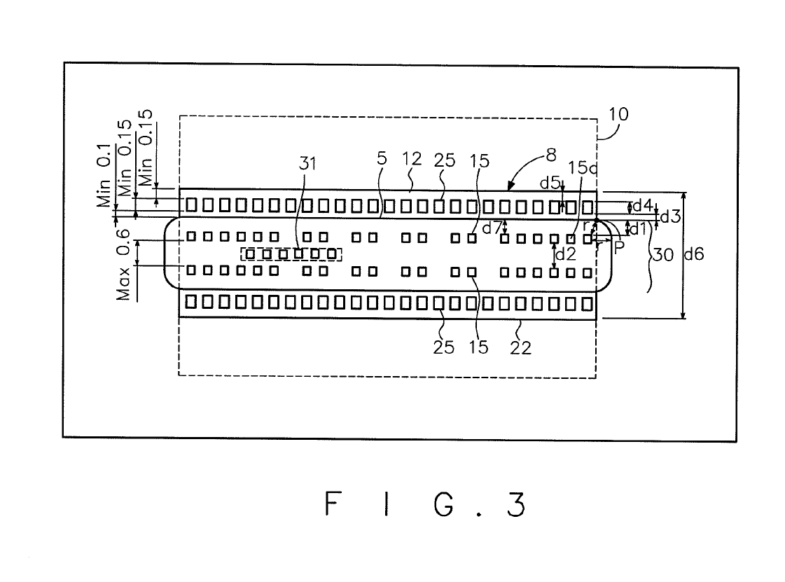

Referring to FIG. 3, the preferred embodiment of a window ball grid array semiconductor package according to the present invention is shown, wherein the elongated slot 30 in the substrate consist of four straight sections and four rounded corners. Each rounded corner is formed between and interconnects the adjacent two of the straight sections of the elongated slot 30. Although a little variation is done on the configuration of the slot 30, the result brings an excellent achievement different from the prior art technology.

As best shown in FIG. 3, when the configuration of the elongated slot 30 is thus altered, the distance d1 between the row of contact pads 15 and the straight section 5 of the elongated slot 30 is measured 0.3 mm, thereby satisfying the requirement of design rule, where the rounded corner has a radius of the minimum distance 0.3 mm or a smaller distance. When the radius of the rounded corner is assigned at 0.3 mm, the distance d7 measured between the straight section 5 of the elongated slot 30 and the row of contact pads 15, and the distance “r” (see FIG. 3) from any point “P” on the rounded corner with respect to the nearest contact pad 15a is measured 0.3 mm.

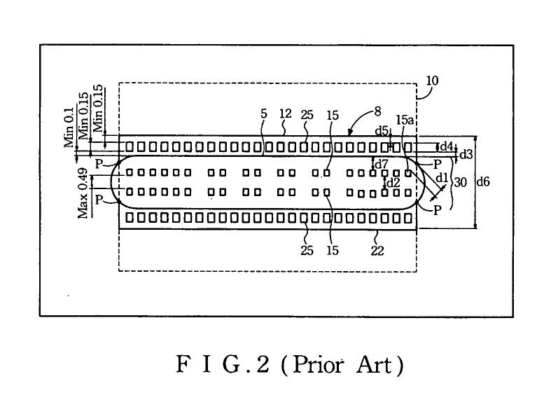

The elongated slot 30 in the substrate 20 in the present semiconductor package is formed by using a drilling machine with a small drill head. The drill head may have a diameter, such as equivalent to 60-70% width of the slot, to form the rounded corner of the elongated slot 30 in FIG. 3 such that the rounded corner of FIG. 3 possesses a t curvature greater than the elongated slot as shown in FIG. 2. It is relatively cheaper to use a drilling machine for forming the elongated slot by comparison with a punch machine having a specific punch head.

Therefore, the distance d2 between two rows of contact pad is increased according to the present invention. According to the measurement, d2=0.6 mm in contrast to d2=0.49 mm of the prior art. In other words, an increase of 22% is achieved according to present invention. Increase of the distance between two rows of contact pad 15 can accommodate a larger number of the electrostatic sensitive devices, electrostatic discharge devices and capacitors. Another advantage is that due to the increased space, injection of the resin for encapsulating the assembly can be conducted with ease and the wires 35 coupling the gold fingers 35 to the contact pads 15 do not snap during the resin injection operation. The yield loss of the window ball grid array semiconductor package of the present invention is smaller than 0.5%.

The following advantages are achieved according to the present invention in compare to the prior art semiconductor package shown in FIG. 2:
(I) the cost of the machine for formation of the slot is reduced when compared to the punching machine and its specific punching head;
(II) the configuration of the slot can satisfy the requirement of design rule, and results in the increased area between two rows of the contact pads to accommodate extra the electrostatic sensitive devices, electrostatic discharge devices and capacitors;
(III) the product yield is increased, i.e. there is no failure in the wire bonding process, the yield loss is smaller than 0.5%.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A window ball grid array semiconductor package comprising:
a substrate formed with an elongated slot therein and having two rows of fingers formed on a front surface of said substrate alongside two sides of said elongated slot, respectively; and
a chip mounted on a rear surface of said substrate, and having two rows of contact pads formed upward corresponding to said two rows of fingers so that bonding wires boned said two rows of contact pads to said two rows of fingers can be through said elongated slot;
wherein, said elongated slot consists of four straight sections and four rounded corners, and every rounded corner has a radius of a minimum distance or beyond full compliance with design rule and wherein said design rule requests a shortest distance between a sidewall of said elongated slot and contact pads of said chip to be WBGA package at least equal or larger than said minimum distance

2. The window ball grid array semiconductor package according to claim 1, wherein the semiconductor package further comprising an extra row of pads on said chip and in between said two rows of pads for an electrostatic protective device and/or a capacitor to be installed.

3. (canceled)

4. The window ball grid array semiconductor package according to claim 1, wherein a mold is disposed on said substrate and having two sides spaced by 2 mm respectively enclosing said two rows of gold fingers therein.

5. The window ball grid array semiconductor package according to claim 1, wherein the minimum distance is 0.3 mm.

6. The window ball grid array semiconductor package according to claim 1, wherein a drill is used for formation of said elongated slot on an upper surface of said substrate.

7. A substrate for window ball grid array (WBGA semiconductor package GA) semiconductor package comprising:
said substrate formed with an elongated slot therein and having two rows of fingers formed on a front surface of said substrate alongside two sides of said elongated slot wherein said elongated slot consists of four straight sections and four rounded corners, every rounded corner having a radius of a minimum distance or a smaller distance fulfill the requirement of design rule, wherein said design rule requests a shortest distance between a sidewall of said elongated slot and contact pads of a chip to be WBGA package at least equal or larger than said minimum distance.
